(19) United States
(12) Patent Application Publication
(10) Pub. No.: US 2009/0015106 A1
(43) Pub. Date: Jan. 15, 2009

(54) Piezoelectric device

(76) Inventor: Hideo Tanaya, Suwa-shi (JP)

Correspondence Address: Baker & Hostetler LLP;Attn: Jim Coffman, 45 Rockefeller Plaza, New York, NY, 10111, US

(21) Appl. No.: 11/726,459

(22) Filed: Mar. 22, 2007

(30) Foreign Application Priority Data
Mar. 22, 2006 (JP) 2006-078887

(51) Int. Cl. H01L 41/053; H01L 41/107; H01L 41/22

(52) U.S. Cl. 310/344; 310/370; 310/357; 29/25.35

(57) ABSTRACT

[Object] To provide a piezoelectric device having excellent drive level characteristics in terms of downsizing, having no remaining stress at the bonding portion of the container and leaving no characteristics deteriorating factors.

[Solving Means] A piezoelectric device includes: a base substrate 54, a framed resonator element 55 stacked and fixed on the base substrate, a lid 56 stacked and fixed on the framed resonator element, wherein the base substrate, the framed resonator element, and the lid are made from the same materials or the materials having highly approximate linear coefficients of expansion and the bonding surfaces thereof are bonded with each other by surface activating process so as to be vacuum-sealed.

### TECHNICAL FIELD

The present invention relates to a piezoelectric resonator element and an improvement of a piezoelectric device having a piezoelectric resonator element housed in a package or case.

### BACKGROUND ART

Piezoelectric devices such as a piezoelectric resonator, a piezoelectric oscillator or the like have been widely used for small information equipment such as hard disc drives (HDDs), mobile computers, and integrated circuit (IC) cards, and for mobile communications equipment such as mobile phones, car-phones, and paging systems, and piezoelectric gyro sensors or the like.

FIG. 13 is a schematic plan view illustrating an example of a piezoelectric resonator element conventionally used in the piezoelectric devices.

In the figure, a piezoelectric resonator element 1, whose shape shown in the figure is formed by etching a piezoelectric material such as quartz or the like, is provided with a base portion 2, and has a rectangular shape, and a pair of vibrating arms 3, 4, which extend from the base portion 2 in the vertical direction shown in the figure. Longitudinal grooves 3a, 4a are formed on the main surfaces (front and back surface) of the vibrating arms, and necessary drive electrodes are formed (See Patent Document 1).

In the piezoelectric resonator element 1, when a driving voltage is applied via a driving electrode, the vibrating arms 3, 4 perform a flexural vibration so that their distal parts move closer and then spread apart, resulting in an output signal having a given frequency.

Here, the piezoelectric resonator element 1, in which lead-out electrodes are formed at the positions respectively indicated by reference numerals 5, 6 on the base portion 2, is bonded and fixed on an inner bottom surface of, for example, a boxy rectangular ceramic package by using adhesives 7, 8 applied on the lead-out electrodes and housed therein.

After bonding by using adhesive, cut parts 9, 9 are formed in the base portion 2 so that the flexural vibration of the vibrating arms is not prevented by remaining stress caused by the differences in the linear expansion coefficient between the material of the package or the like, and the material of the piezoelectric resonator element.

### [Patent Document 1] JP 2002-261575 A

### [Patent Document 2] JP 2000-68780 A

### DISCLOSURE OF THE INVENTION

### Problem to be solved by the Invention

In the piezoelectric resonator element 1, as a result of miniaturization, the width W1, W1 of each of the vibrating arms 3, 4 is approximately 100 μm, the distance MW1 between them is approximately 100 μm, and the width BW1 of the base portion 2 is approximately 500 μm. These parts are miniaturized, so that the length BL1 of the base is accordingly shortened. As a result, the piezoelectric resonator element 1 is miniaturized.

However, the piezoelectric resonator element 1, which is miniaturized, has the problem in that even the bonding of the thus miniaturized piezoelectric resonator element 1 in a ceramic package is hardly performed without any disadvantage in that the distal end of the vibrating arm is lowered to come into contact with the bottom surface.

Further, the piezoelectric resonator element subjected to bonding by fixing the positions of the base portion 2 denoted by reference symbols 5, 6 is likely to be damaged due to drop impact of the device. When the amount of adhesives 7, 8 applied on the base portion 2 is increased in order to avoid this problem, the flexural vibration of the vibrating arm is hindered, thereby causing a problem in that the crystal impedance (CI) value may increase or the drive characteristics are deteriorated.

In view of the above, in order to avoid such problem, there is long known a technique disclosed in, for example, Patent Document 2.

Patent Document 2 has been disclosed earlier than Patent Document 1. According to this document, a crystal resonator element 60 with an outer frame 50 integrally formed therewith is stacked on a glass case 70 having a recess, and a glass lid 10 is then staked thereon and those are subjected to anodic bonding (see FIG. 1, FIG. 3 of Patent Document 2).

However, according to Patent Document 2, there is used anodic bonding technique, so a framed resonator made from crystal is held between the glasses formed by different materials to be subjected to bonding. The materials having different linear coefficients of thermal expansion are bonded with each other, stress remains at the corresponding bonding portion, which becomes a factor of characteristics deterioration.

The invention is made in order to solve the above mentioned problems and has an object to provide a piezoelectric device having excellent drive level characteristics in terms of downsizing, having no remaining stress at the bonding portion of the container and leaving no characteristics deteriorating factors.

### Means for Solving the Problems

The above object is solved, according to a first invention, by a piezoelectric device, including: a base substrate, a framed resonator element stacked and fixed on the base substrate, a lid stacked and fixed on the framed resonator element, in which the base substrate, the framed resonator element, and the lid are made from the same materials or the materials having highly approximate linear coefficients of expansion and the bonding surfaces thereof are bonded with each other by surface activating process so as to be vacuum-sealed.

According to the construction of the first invention, the piezoelectric device has a structure in which the package containing the piezoelectric resonator element is formed by the base substrate and the frame portion of the framed resonator element stacked thereon and a lid is then stacked thereon before performing airtight sealing.

Therefore, the piezoelectric resonator element is integrally formed with the frame portion, it is not necessary to bond it on the package by using adhesive or the like and no difficulty in bonding occurs even if it is downsized.

Further, the base substrate, the framed resonator element stacked and fixed on the base substrate, and a lid stacked and fixed on the framed resonator element are formed from the same materials or the materials having highly approximate linear coefficients of expansion, so even if they are bonded with each other in a stacked manner stress due to change in temperature environment is not applied to the bonding portions.

Furthermore, the respective bonding surfaces of the base substrate, the framed resonator element, and the lid are subjected to, for example, plasma irradiation, thereby making it possible to perform bonding even in the case of the same materials.

As thus described above, it is possible to provide a piezoelectric device having excellent drive level characteristics in terms of downsizing, having no remaining stress at the bonding portion of the container and leaving no characteristics deteriorating factors.

As second invention is characterized in that, in the construction of the first invention, the base substrate, the framed resonator element, and the lid are all made from quartzes having the same cut angle.

According to the construction of the second invention, the framed resonator element is made from quartzes having the same cut angle, thereby making it possible to obtain a piezoelectric resonator element having appropriate piezoelectric operation due to its piezoelectric effects. Further, the base substrate, and the lid are made from quartzes having the same cut angle as this framed resonator element, they share many characteristics such as linear coefficients of thermal expansion, thereby making it possible to obtain preferable characteristics such as no remaining deformation due to extra stress in the case of bonding them with each other.

A third invention is characterized in that, in the construction of the first invention or the second invention, the frame resonator element has a piezoelectric resonator element portion and a frame portion formed so as to surround the piezoelectric resonator element portion; a resonator element main body as the piezoelectric resonator element portion has a base portion inwardly extending, within the frame portion, from a side constituting the frame portion and a plurality of vibrating arms extending from the base portion; a longitudinal groove is formed on each of the plurality of vibrating arms, the longitudinal groove formed on the main surface of the vibrating arms in longitudinal direction and having a drive electrode therewithin; and a width dimension of each of the vibrating arms has a reduced width part gradually reducing its width from the base portion side toward the distal end side, a changing point P of width change is located on the distal end side, at which the width dimension extends with an equal amount or increases, and the changing point P is located nearer to vibrating arm distal end side than the distal part of the longitudinal groove.

According to the construction of the third invention, when an electrode for driving (excitation electrode) is formed in the longitudinal groove formed in the vibrating arm, electric field efficiency is enhanced. In the case of providing the longitudinal groove, the width dimension of the arm gradually reduces from the base portion side toward the distal end side and there is provided a changing point P of width change, which is located on the distal end side, at which the width dimension increases, so it is possible to prevent oscillation in the second harmonic while suppressing the CI value.

A fourth invention is characterized in that, in the construction of the third invention, the width dimension of each of the vibrating arms has a first reduced width part drastically reducing its width from a footing part of the vibrating arm to the base portion toward the distal part thereof, and a second reduced width part gradually decreasing its width as a reduced width part from the end of the first reduced width part further toward the distal part thereof.

According to the construction of the fourth invention, there are provided the second reduced width part gradually decreasing its width as a reduced width part from the end of the first reduced width part further toward the distal part thereof so that the arm width of the vibrating arm gradually reduces, and a changing point P of width change located on the distal end side, at which the width dimension increases, thereby making it possible to prevent oscillation in the second harmonic while suppressing the CI value.

Further, there is provided a first reduced width part drastically reducing its width from a footing part of the vibrating arm to the base portion toward the distal part thereof, so the stiffness of the footing part on which most large stress acts and which is greatly deformed when the vibrating arm performs flexural vibration can be enhanced. By this, the flexural vibration of the vibrating arm becomes stable and the vibrating components in the undesired direction are suppressed, so the CI value can be yet further reduced. That is to say, for downsizing the piezoelectric resonator element, it is possible to realize stable flexural vibration and keep the CI value low.

A fifth invention is characterized in that, in the construction according to the third invention of the fourth invention, the base portion has a cut portion formed to be reduced in its width.

According to the construction of the fifth invention, there is provided the cut portion formed such that the lateral peripheral portion of the base portion is partially reduced in its width in the width direction, so it is possible to prevent the vibration leakage due to flexural vibration of the vibrating arm from reaching the frame portion via the base portion, thereby making it possible to prevent or more reliably prevent the increase of the CI value.

A sixth invention is characterized in that, in the construction of the fifth invention, the cut portion is formed on the base portion with a more than 1.2 times distance of the arm width from the footing part of each of the vibrating arms.

According to the construction of the sixth invention, the arm width dimension W2 is correlated to the range of propagation of the vibration leakage when the vibrating arm of the tuning-fork-like type resonator element performs flexural vibration. In view of this, the position, at which the cut portion is provided, is made to be located at the position, the distance from which to the proximal portion of the vibrating arm exceeds the arm width dimension W2 of the vibrating arm. By this, the cut portion is structured such that the vibration leakage from the vibrating arm is more reliably prevented form reaching the base portion side. Therefore, it becomes possible to provide a piezoelectric device having excellent drive level characteristics by appropriately preventing the vibration leakage from the vibrating arm side toward the base portion side.

A seventh invention is characterized in that, in the construction according to any one of the first to the sixth inventions, the base portion is provided with a through-hole located at the position closer to the vibrating arm than the position, at which the frame portion is integrally connected to the base portion.

According to the construction of the seventh invention, a through-hole located at the position closer to the vibrating arm than the position, at which the frame portion is integrally connected to the base portion, so it becomes possible to yet further prevent vibration leakage without greatly reducing the stiffness of the base portion as compared with the case in which instead of the through-hole a cut out portion is deeply formed in the lateral peripheral portion of the base portion.

An eight invention is characterized in that, in the construction according to the third to the seventh inventions, an irregular shaped part projecting in a plus X-axis (electric axis) direction of less than 5 μm is formed on a lateral surface of each of the vibrating arms.

According to the construction of the eight inventions, the irregular shaped part is formed so as to have the minimum size of less than 5 μm formed by utilizing etching anisotropic nature in the case of performing wet etching for the outer shape formation of the piezoelectric resonator element, flexural vibration of the vibrating arm can be made stable.

The ninth invention is characterized in that, in the construction according to the third to the eighth inventions, the center position in width dimension of the longitudinal groove of each of the vibrating arms is shifted in a minus X-axis direction from the center position of the arm width dimension.

According to the construction of the ninth invention, during forming the framed resonator element, the walls have different thicknesses, between which the longitudinal groove provided in the vibrating arm is sandwiched, that is to say, the minus X-axis side wall has larger thickness. Therefore, the center position in width direction of the longitudinal groove does not pass through the position of the center of gravity in the width direction of the vibrating arm in the case of the conventional formation position, thereby hindering flexural vibration of the vibrating arm.

In view of this, as the center position in width direction of the longitudinal groove is shifted in the minus X-axis direction, that is to say, the center position in width direction of the longitudinal groove is displaced in the minus X-axis direction, the center position in the width direction of the longitudinal groove comes closer to the position of the center of gravity in the width direction of the vibrating arm, so the mass balance of left and right of the vibrating arm can be adjusted. By this, it is possible to provide a piezoelectric device having excellent drive characteristics while realizing stable flexural vibration of the vibrating arm even if the piezoelectric resonator element is downsized, the longitudinal groove has shorter groove width, and the fin becomes smaller.

Moreover, the above-mentioned object is, according to a tenth invention, achieved by A method for manufacturing a piezoelectric device, characterized by comprising the steps of forming a base substrate layer constituting base substrate, an element layer constituting a framed piezoelectric resonator element, and a lid layer constituting a lid, the layers being formed from the same materials or the materials having highly approximate linear coefficients of expansion and having the sizes corresponding to the same numbers of a plurality of products; performing surface activating to bonding surfaces of the base substrate layer, the element layer, and the lid layer; staking and pressurizing the layers to bond the same with each other; and cutting the respective layers into a piece of a size corresponding to the respective product.

According to the tenth invention, the base substrate, the framed resonator element stacked and fixed on the base substrate, and a lid stacked and fixed on the framed resonator element are formed from the same materials or the materials having highly approximate linear coefficients of expansion, so even if they are bonded with each other in a stacked manner stress due to change in temperature environment is not applied to the bonding portions.

Further, the respective bonding surfaces of the base substrate layer, the element layer and the lid layer are subjected to plasma irradiation in advance so as to activate the bonding surfaces, it becomes possible to realize a structure in which the layers can be adequately bonded with each other even in the case of the same materials. Then, the cutting process is performed by dicing after bonding, production becomes efficient. Further, it becomes possible to provide a method for manufacturing in terms of downsizing, having no remaining stress at the bonding portion of the container and leaving no characteristics deteriorating factors.

An eleventh invention is characterized in that, in the tenth invention, the step of staking and pressurizing the layers is carried out in vacuum so that airtight sealing is performed.

According to the construction of the eleventh invention, by performing pressurizing and bonding in vacuum and vacuum-sealing the inside of the package or case at a high accuracy, the vibration performance of the piezoelectric resonator element housed therein is not impaired. Therefore, it becomes possible to achieve low crystal impedance (CI) value at a practicable value.

A twelfth invention is characterized in that, in the construction of the tenth invention, the step of staking and pressurizing is carried out in atmosphere and then hole sealing is performed in vacuum so that airtight sealing is performed.

According to the construction of the twelfth invention, the step of pressurizing and bonding can be performed in atmosphere, the arrangement of the steps are simplified as no vacuum apparatus is used, so the method can be easily carried out. Further, by performing hole sealing in vacuum, it becomes possible to seal the inside of package or case airtight at even higher degree of vacuum.

A thirteenth invention is characterized in that, in the construction according to the tenth to the twelfth inventions, plasma irradiation of the bonding surfaces is carried out in vacuum prior to the respective bonding surfaces of the element layer and the base substrate layer or of the element layer and the lid layer and those are aligned in atmosphere and subjected to bonding process for bonding; and that the other bonding surface is then subjected to plasma irradiation in vacuum and aligned in atmosphere before being subjected to bonding process in vacuum.

According to the construction of the thirteenth invention, it is possible to carry out plasma irradiation and the bonding process completely separately, the apparatus size can be small as compared with the method, according to which those steps are continuously performed using the same apparatus. By preparing an apparatus suitable for the capacities of the respective steps, efficient production can be achieved.

### BRIEF DESCRIPTION OF THE DRAWINGS

FIG. 1 A schematic sectional view illustrating an embodiment of a piezoelectric device according to the invention.

FIG. 2 A view showing a framed resonator element.

FIG. 3 A view showing a base substrate.

FIG. 4 A schematic plan view illustrating the framed resonator element of FIG. 2 in details.

FIG. 5 A sectional end view taken along with the line A-A of the vibrating arm portion of FIG. 4.

FIG. 6 A sectional end view taken along with the line B-B of FIG. 4.

FIG. 7 A circuit chart illustrating an example of an oscillation circuit in the case in which the piezoelectric device according to this embodiment is utilized to constitute a piezoelectric oscillator.

FIG. 8 A flow chart showing a first embodiment of a method for manufacturing the piezoelectric device of FIG. 1.

FIG. 9 An exploded perspective view showing a part of the steps of FIG. 1.

FIG. 10 A flow chart showing a second embodiment of a method for manufacturing the piezoelectric device of FIG. 1.

FIG. 11 A flow chart showing a third embodiment of a method for manufacturing the piezoelectric device of FIG. 1.

FIG. 12 A view showing coordinate axes of a crystal Z plate.

FIG. 13 A schematic plan view showing a conventional piezoelectric resonator element.

### DESCRIPTION OF THE REFERENCE NUMERALS

| | | | | | |
|---|---|---|---|---|---|
| 30 | piezoelectric device | 32 | resonator element main body | 33, | |
| 34 | longitudinal groove | 35, 36 | vibrating arm | 54 | frame portion |
| 55 | framed resonator element | 56 | lid | 71, 72 | cut portion |
| 80 | through-hole | | | | |

### BEST MODE FOR CARRYING OUT THE INVENTION

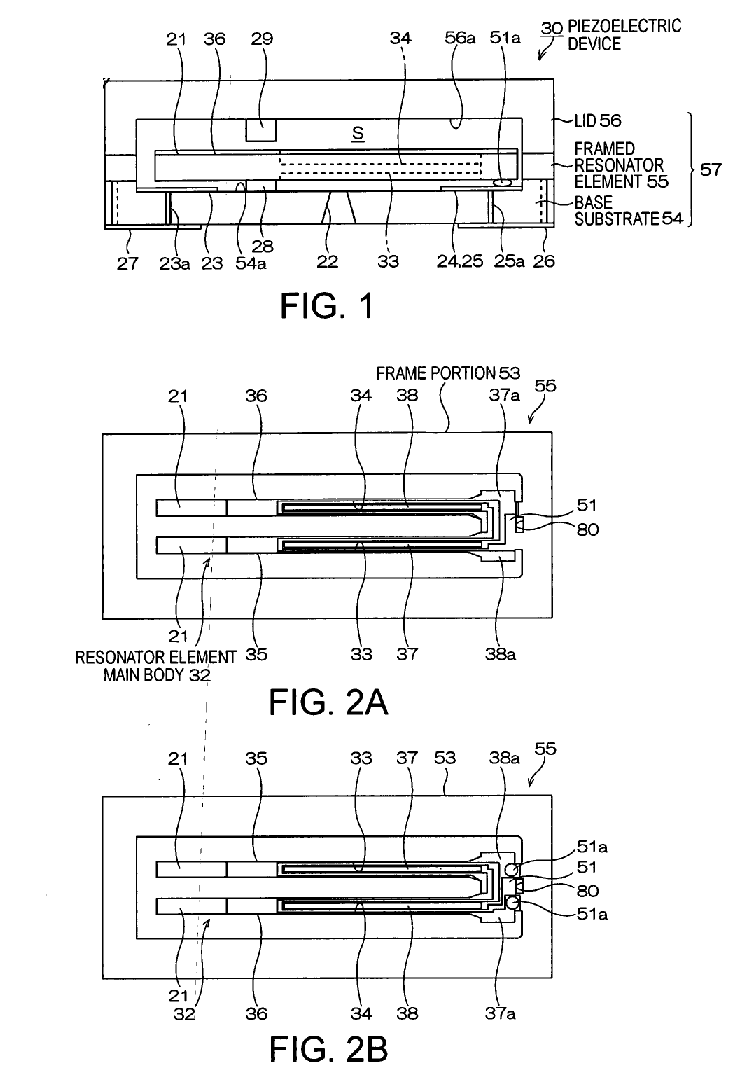

FIG. 1 shows an embodiment of a piezoelectric device according to the invention and is a longitudinal sectional view thereof.

In the figure, there is exemplified a piezoelectric device 30 constructed by a piezoelectric resonator. The piezoelectric device 30 contains a piezoelectric resonator element in a package 57.

To be more specific, the piezoelectric device 30 has a base substrate 54 as an insulating substrate, a framed resonator element 55 stacked and fixed on the base substrate 54, and a lid 56 stacked and fixed on the framed resonator element 55.

In the case of this piezoelectric device 30, the above-mentioned package 57 contains the piezoelectric resonator element hermetically and is so constructed as to include the base substrate 54, the framed portion of the frame resonator element 55 and the lid 56. The outer shapes of the base substrate 54, the frame portion of the framed resonator element 55 and the lid 56 coincide with each other.

The base substrate 54 is an insulating substrate and is made from an insulating material described later. This base substrate 54 forms the bottom portion of the package 57.

The framed resonator element 55 is made from a piezoelectric material. As a piezoelectric material for forming this framed resonator element 55, quartz is used in this embodiment. It is possible to use other than quartz a piezoelectric material such as lithium tantalate, lithium niobate or the like. In particular, a wafer formed by a quartz Z plate is used in this embodiment. The cutting angle of quartz will be described later in details.

FIG. 2(a) shows a schematic plan view of this framed resonator element 55 and the FIG. 2(b) shows a schematic bottom (back-side) view thereof.

In those figures, the framed resonator element 55 has, according to this embodiment, a rectangular frame portion 53 having longer side in one direction and a base portion 51 formed so as to extend inwardly from one side of the frame portion 53 therewithin while constituting one piece with the frame portion 53, and a pair of vibrating arms 35, 36 extending from the base portion 51 in parallel to each other in the left direction of the figures, for example.

In each of the vibrating arms, there are formed, for example, a longitudinal groove, in which an excitation electrode is formed as a drive electrode. The excitation electrode in the respective longitudinal groove is a counterpart of a lateral surface electrode described later and serves as a heteropolar electrode thereto. The excitation electrode forms an electronic field inside the resonator element main body 32 efficiently. Further, on each of the distal end sides of each of the vibrating arms 35, 36, there is formed a metal coating 21, 21 that serves as weight for frequency adjustment (fine adjustment) described later.

The lid 56 is a lid body, is fixed on the framed resonator element 55 as described later and seals space, in which the piezoelectric resonator main body 32 is contained, hermetically.

In particular, in this embodiment, for the lid 56, a material, through which light (for example, laser light) for frequency adjustment passes, is preferably selected and a transparent material is suitable. The lid 56 is formed as described later. The lid is preferably formed by a quartz Z plate, for example, since the same material as the framed resonator element 55, which is the object to be bonded, can be used and the same linear coefficient of expansion can be obtained. Other than this, it is possible to use high-expansion glass or high-expansion glass ceramics, for example. Note that the same material can be used for the base substrate 54.

As shown in FIG. 1, the lid 56 is provided with a recess 56a in its inside and a buffer projection 29 extending inwardly (downwardly) from the recess 56a. The recess 56a is formed so as to cover the entire inside and constitutes the upper portion of inner space S of the package 57. Note that the buffer projection 29 is provided so as to avoid large vibration of the resonator element main body 32 when it vibrates upwardly upon impact from outside or the like to hit on and damage the inner surface of the lid 56.

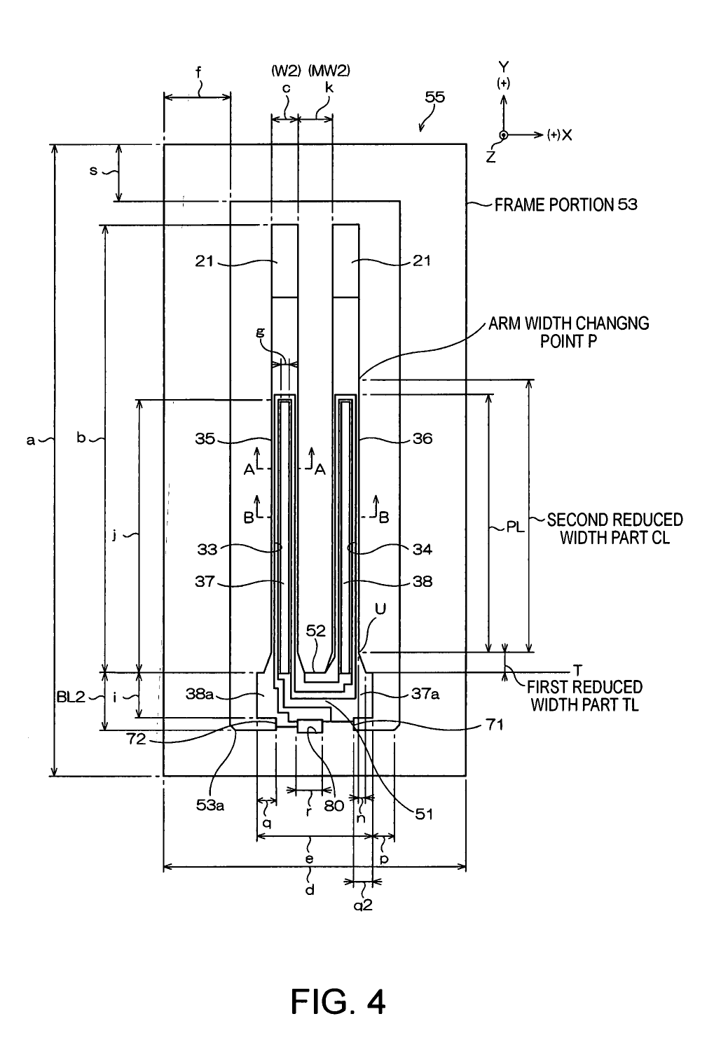

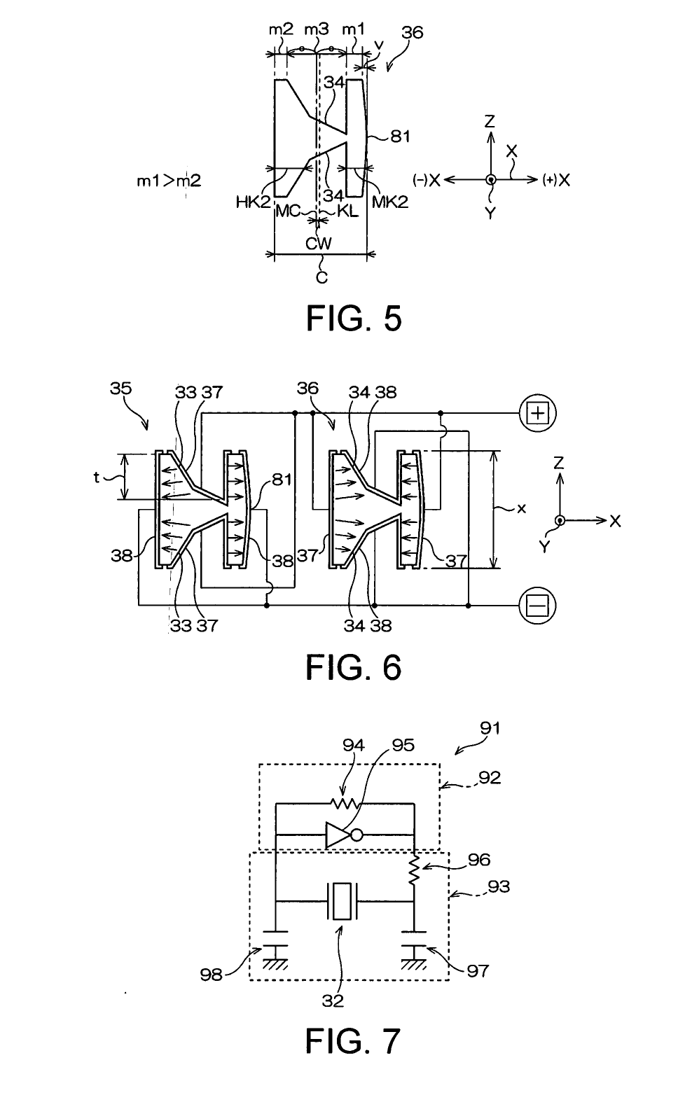

FIG. 4 shows a detailed plan view of the above-mentioned framed resonator element 55. FIG. 5 shows a sectional end view taken along the line A-A of FIG. 4 and FIG. 6 shows a sectional end view taken along the line B-B of FIG. 4.

Referring to those figures, the resonator element main body 32, which is a piezoelectric resonator element of the framed resonator element 55, will be described in particular detail.

As shown in FIG. 4, the resonator element main body 32 has the base portion 51, the pair of vibrating arms 35, 36 starting from one end of the base portion 51 (the upper end shown in figure) upwardly to be divided into two and extend in parallel to each other.

On the front and back surface of the main surface of each of the vibrating arms 35, 36, longitudinal grooves 33, 34 extending in the longitudinal direction are preferably formed. As shown in FIG. 6, excitation electrodes 37, 38 each serving as drive electrodes are disposed in the longitudinal grooves.

Preferably, the distal portion of each of the vibrating arms 35, 36 is gradually widened in the width so as to be slightly tapered, thereby serving as a plummet with increased weight. As a result, the vibrating arms easily perform flexural vibration.

The framed resonator element 55 including the outer shape of the tuning-fork-like shape of the resonator element main boy 32 and the longitudinal groove provided in each of the vibrating arms can be precisely formed by, for example, wet etching a material such as a quartz wafer or the like with a fluorinated solution or by dry etching.

As shown in FIG. 6, the excitation electrodes 37, 38 are respectively formed in the longitudinal grooves 33, 34, and the respective side surfaces of the vibrating arms. In each of the vibrating arms, the electrode formed in the longitudinal groove and the electrode formed on the side surface are paired. Each of the excitation electrodes 37, 38 are routed through the base portion 51 except the frame portion 53 respectively as lead-out electrodes 37a, 38a. It will be described later in details how to establish the connection which enables the transmission of the drive voltage form the outside to the resonator element main body 32 in the case in which the piezoelectric device 30 is mounted on a mounting substrate or the like.

In this embodiment, by employing the structure described later, drive voltage is respectively applied to the excitation electrodes in the longitudinal grooves 33, 34, thereby making it possible to enhance the electric field efficiency inside of the region in which the longitudinal grooves in the each of the vibrating arms at the time of driving.

In this case, as shown in FIG. 6, each of the exciting electrodes 37, 38 is connected to an alternating current power supply source with a cross wiring. An alternating voltage serving as a driving voltage is applied to each of the vibrating arms 35, 36 from the power supply source.

Accordingly, the vibrating arms 35, 36 are excited so as to vibrate with a reversed phase from each other. In a fundamental mode, i.e. fundamental wave, the vibrating arms 35, 36 perform a flexural vibration so that their distal parts move close to and spread away from each other.

Here, the fundamental wave of the resonator element main body 32 is, for example, as follows: Q value is 12000; capacitance ratio (C0/C1) is 260; CI value is 57 k. OMEGA; and frequency is 32.768 kHz (kilo hertz, hereinafter referred to as kHz).

Also, the second harmonic wave is, for example, as follows: Q value is 28000; capacitance ration (C0/C1) is 5100; CI value is 77 k. OMEGA; and frequency is 207 kHz.

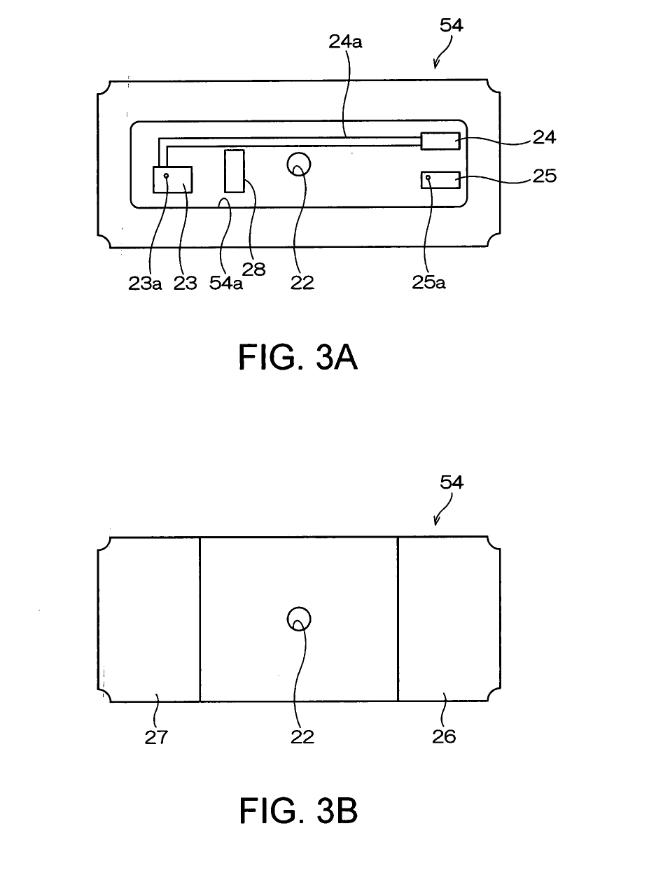

FIG. 3 shows the base substrate. FIG. 3(a) shows a schematic plan view of this base substrate 54 and FIG. 3(b) shows a schematic bottom view thereof.

The base substrate 54 is made from the same material as the lid and the framed resonator element and has plate-like shape.

As shown in FIG. 3(a) and FIG. 1, the surface of the base substrate 54 serves as the inner bottom surface of the package 57.

As shown in FIG. 1, the base substrate 54 is provided with a recess 54a in its inside and a buffer projection 28 projecting inwardly (upwardly) from the recess 54a. The recess 54a is formed over the entire inside portion of the base substrate 54 and forms the lower part of the inner space S of the package 57. Note that the buffer projection 28 is provided so as to avoid large vibration of the resonator element main body 32 when it vibrates downwardly upon impact from outside or the like to hit on and damage the inner surface of the base substrate 54.

As shown in FIG. 3(a), in the vicinity of one end in the longitudinal direction of the surface of the base substrate 54, there is formed an electrode part 23. Further, on the other end opposite in the longitudinal direction of surface of the base substrate 54, there are formed electrode parts 24, 25 in parallel to each other. The electrode part 24 and the electrode part 25 are electrically connected with each other by a conducting pattern 24a.

As shown in FIG. 1 and FIG. 2(a), on the back surface of the base substrate 54, mounting electrodes 26, 27 are formed on the respective ends in the longitudinal direction of the base substrate.

As is understood by referring to FIG. 3(a) and FIG. 1, the electrode part 23 is electrically connected to the mounting electrode 27 through a conductive through hole 23a provided on the electrode part 23 of the base substrate 54 and the electrode part 24 is electrically connected to the mounting electrode 26 thorough a conductive through hole 24a provided on the electrode part 24 of the base substrate 54.

Furthermore, in the center of the base substrate 54, a through-hole 22 is preferably formed. As shown in FIG. 1, the diameter of the through-hole 22 is gradually widened outwardly and serves as a through-hole for hole sealing during manufacturing process as described later. To be more specific, the through-hole 22 is sealed up by metal filling material after internal gas or the like at the time of bonding via the through hole 22, thereby making the inside thereof airtight. This through-hole 22 can be omitted but is needed in order to perform hole sealing process, as described later in the case of a third embodiment.

As shown in FIG. 1 and FIG. 2(a), a metal bump 51a is disposed between the lead-out electrode 37a of the resonator element main body 32 and the electrode part 24 of the base substrate 54. That is to say, since the metal bump 51a is thus disposed between the lead-out electrode 38a of the resonator element main body 32 and the electrode part 25 of the base substrate 54, the resonator element main body 32, the base substrate 54 and its mounting terminals 26, 27 are electrically connected to each other. Note that for the electrical connection between the lead-out electrode 38a of the resonator element main body 32 and the electrode part 25 of the base substrate 54 a brazing filler material other than metal bump may be used; However, it is better to use the metal bump since it makes it possible to utilize limited space and establish electrical connection more easily.

With reference to FIG. 4, the resonator element main body 32 will be described in details.

As shown in FIG. 4, it is preferable that recess or cut portions 71, 72, which is formed by partially shortening the dimension in width direction of the base portion 51 be provided on each lateral peripheral portions so as to be spaced sufficiently apart from the respective ends on the vibrating arm side of the base portion 51. It is preferable to reduce the depths (dimension q in FIG. 4) of the cut portions 71, 72 in width direction to the extend that they respectively coincide with the lateral peripheral portion of the outside of the vibrating arms 35, 36, in the vicinity of which each of the cut portions is disposed.

By this, the vibration leakage from the vibrating arms 35 and 36, when they perform the flexural vibration, is hardly propagated to the base portion 51 side, thereby reaching the frame portion 53 so as to keep the CI value low.

Making the depth dimension of the cut portions 71, 72 larger is effective for suppressing the vibration leakage, the stiffness of the base portion 51 itself becomes unnecessarily lower, thereby hindering the stable flexural vibration of the vibrating arms 35, 36.

In view of the above, according to this embodiment, the through-hole 80 is formed at the position which is in the vicinity of the center of base portion 51 in width direction and closer to the vibrating arms 35, 36 than to a connecting portion 53a, at which the frame portion 53 is integrally connected with the base portion 51.

The through-hole 80 is, for example a rectangular hole passing between the front and back of the base portion 51. The shape of the through-hole is not limited thereto; A circular hole, an ellipse hole or a square hole is also possible.

By so doing, as compared with the case in which the cut portions 71, 72 is made deeper, it becomes possible to further suppress the vibration leakage and to reduce the CI value.

Here, the length r of the through-hole 80 in width direction of the base portion 51 is preferably about 50 μm. The ration of the dimension e with respect to the dimension r of the through-hole 80 and the depth q of the above-mentioned cut portion 71, that is, (r+q)/e is preferably 30% to 80%, thereby producing the effect of reducing the vibration leakage and suppressing the influences of the bonding portions via frame portion 53.

When the left cut portion is q and the right cut portion is q2, it is preferable when (r+q+q2)/e is about 30%.

Further, according to this embodiment, in order to downsize the package dimension, the distance (dimension p) between the lateral surface of the base portion 51 and the frame portion 53 is 30 μm to 100 μm.

Further, according to the embodiment, as shown in FIG. 4, the portion, along which the above-mentioned frame portion 53 extends, that is, the other end portion 53a (connecting portion) of the base portion 51 is located so as to keep the distance BL2 sufficiently spaced apart from a footing part 52 of the vibrating arms 35, 36.

The dimension of the distance BL2 preferably exceeds the arm width dimension c (W2) of the vibrating arms 35, 36.

Namely, when the vibrating arms 35, 36 of the tuning fork type resonator element perform the flexural vibration, the area in which the vibration leakage propagates toward the base portion 51 has a relative correlation with the arm width dimension W2 of the vibrating arms 35, 36. The inventor focuses attention to this point, having knowledge that the position serving as the base end of the frame portion 53 should be disposed at the proper position.

Therefore, according to this embodiment, a structure can be achieved in which the vibration leakage from the vibrating arms 35, 36 is more surely suppressed from propagating to the frame portion 53 side in the following manner: the position of the portion 53a (connecting portion), which serves as the base end of the frame portion 53, is chosen so that the distance from the footing part 52 of the vibrating arms to the portion 53a exceeds the dimension corresponding to the size of the arm width dimension W2 of the vibrating arms. Therefore, in order to reduce the CI value and to obtain advantageous effects of performing bonding and fixing at the frame portion 53 as described later, it is preferable that the position of the portion 53a is spaced apart from the footing part 52 (i.e. the one end portion of the base portion 51) of the vibrating arms 35, 36 by the distance BL2.

For the same reason, it is preferable that the positions at which the cut portions 71, 72 are formed are spaced apart from the footing part 52 of the vibrating arms 35, 36 by a distance that exceeds the dimension of the arm width W2 of the vibrating arms 35, 36. Therefore, the cut portions 71, 72 are formed at the positions, which include a part where the frame portion 53 is integrally connected to the base portion 51, and are closer to the vibrating arms than to the above mentioned part.

Moreover, it has been shown that by forming the cut portions 71, 72 apart from the footing (proximal) portion by more than 1.2 time the above-mentioned arm width dimension W2, drive level characteristics can be adjusted to the level of normal piezoelectric resonator element.

As thus described above, according to this embodiment, the arm width W2 of the vibrating arms is about 40 μm to 60 μm, and the distance k (MW2) between the vibrating arms is about 50 μm to 100 μm.

Further, according to this embodiment, preferably, the width dimension s of the frame portion 53 in Y direction is about 100 μm, the width dimension thereof in X direction is 200 μm, and the width dimension of the frame is 50 μm to 300 μm. That is to say, with regard to the width dimension of the frame, it is preferable that the dimension s be smaller than the dimension f. The resonator element main body 32 downsized has larger dimension in length direction (Y direction) from the viewpoint of dimension balance, so it is preferable that the dimension s be smaller in order to make the framed resonator element 55 smaller. Further, the frame portion 53 serves as a bonding portion, it is possible to suppress the stress acting on the frame portion 53 by making the dimension f larger.

As thus dimensioned described above, this embodiment makes it possible to achieve downsizing and obtain the following operation effects.

In the resonator element main body 32 in FIG. 1, the piezoelectric resonator element is, unlike the conventional case, not bonded to the package by adhesive but is integrated in the package through the frame portion 53. Therefore, the stress change, which is produced at the bonding position due to the change of surrounding temperature or drop shock or the like, hardly affects the vibrating arms 35, 36 due to the crooked distance from the bonding position of the frame portion 53 to the other end portion 53a of the base portion 51, and further the distance of the length of the base portion 51, which is longer than the distance BL2. As a result, the assembly exhibits particularly good temperature characteristics.

In contrast, the vibration leakage from the vibrating arms 35, 36, which perform the flexural vibration, is hardly propagated to the frame portion 53, since the vibration leakage reaches the frame portion 53 after passing through the base portion 51 including the given length that is longer than the distance BL2.

Here, if the length of the base portion 51 is extremely short, a situation that is difficult to control may occur since a leaked component of the flexural vibration spreads over the frame portion 53. However, according to this embodiment, such situation is thoroughly avoided.

In addition to the advantageous effects, since the frame portion 53 is connected at the other end portion 53a (connecting portion) of the base portion 51 thereto, and integrated in the package 57, the size of the entire assembly can be made compact.

Moreover, as compared with the structure of FIG. 14, the following can easily be understood: As shown in FIG. 13, conductive adhesives 7, 8 are applied to the lead out electrode 5 and the lead-out electrode 6, both of which are closely located. Due to this structure, the bonding process should be carried out by applying the adhesive to extremely narrow areas (of the package) so that they do not contact each other for avoiding a short, and by paying attention, even after bonding, not to flow out the adhesive to cause a short before curing it so that the process becomes difficult.

In contrast, in the resonator element main body 32 in FIG. 1, the frame portion 53 is to be bonded integrally with the package, therefore the difficulties as above described can be avoided and there are no worries of short circuiting.

FIG. 5 is a sectional end view taken along with the line A-A showing the sectional end surface of the vibrating arm 36, in which the excitation electrode is omitted for the sake of the convenience of drawing and the easiness of understanding. Note that the sectional end surface of the vibrating arm 35 has the same shape, therefore the view and the explanation thereof will be omitted and the vibrating arm 36 only will be described.

As described above, the main surfaces of the vibrating arm 36, that is, the front surface and the back surface (top surface and the bottom surface) in this embodiment are respectively provided with longitudinal grooves 34, 34 extending in the longitudinal direction. In this case, the broken line KL shown relates to the center position regarding the arm width dimension c of the vibrating arm 35.

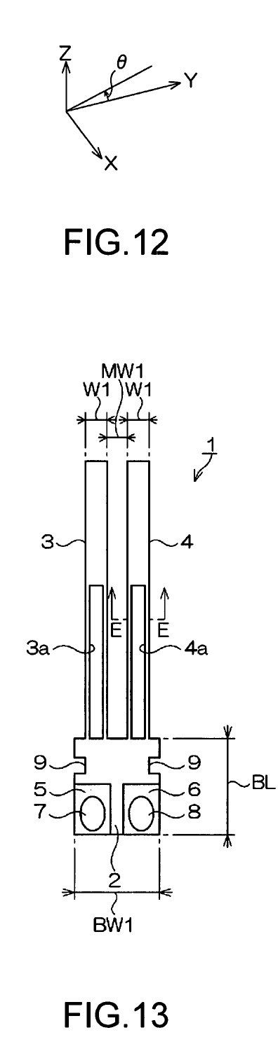

Here, the piezoelectric resonator element according to this embodiment is formed by using a quartz wafer having a size enabling division thereof into several or man of the resonator element main body 32 integrally with the frame portion 53. That is to say, the element layer, which will be also described with regard to the process described later, is ct from a piezoelectric material, for example a single crystal of quartz, so that the X-axis is electrical axis, the Y-axis is mechanical axis, and the Z-axis is optical axis, as shown in FIG. 4. Further, when the above-mentioned quartz wafer is cut from a single crystal of quartz, a quartz Z plate is cut by being rotated within a range of zero to five degrees in clock wise direction about the Z-axis (θ shown in FIG. 12) in the orthogonal coordinate system composed of the X, Y, and Z-axes, being cut and polished to a given thickness.

As shown in FIG. 5, with regard to the vibrating arm 36, of the thickness dimensions HK2 and MK2 of both walls, between which the longitudinal groove 34 exists, the dimension HK2, which is at the minus X-axis side, is larger. Therefore, the center of gravity of the vibrating arm 36 exists clearly closer to the minus X-axis side than the above-mentioned center line KL.

Thus, according to this embodiment, the positions, at which the longitudinal grooves 34, 34 are formed, is shifted and (the center position in width of) the longitudinal grooves 34, 34 are decentered so as to be closer to the minus X-axis side than usual.

The reason for this is as follows: In the case of the vibrating arm 36 shown in FIG. 5, when the center position in width direction of the longitudinal groove 34 coincides with the center position in arm width direction (see FIG. 13), the center in width direction of the longitudinal groove 34 does not pass through the position of center of the gravity, resulting in that the flexural vibration of the vibrating arm is hindered.

Therefore, as described above, by shifting the center position in width of the longitudinal groove 34 in the minus X-axis direction, this center position MC in width of the longitudinal groove 34 is located yet closer to the position of center of the gravity in width direction of the vibrating arm, thereby making it possible to adjust the mass balance of the left and right sides of the vibrating arm. By this, it is possible to provide a resonator element main body 32 having excellent drive level characteristics while achieving stable flexural vibration of the vibrating arms, even when the piezoelectric resonator element is downsized and the groove width of the longitudinal groove is made shorter and a fin 81 (described later) is made smaller.

Here, in order to achieve the above-described structure, it is preferable to perform half etching by, for example, shifting a mask for etching close to the minus X-axis side by distance CW during the etching (half etching) process of the longitudinal groove (described later), unlike the conventional case in which the region of the etching is about the center line KL.

In this case, after the formation of the longitudinal grooves 34, 34, as shown in FIG. 6, as to the distance between the outer peripheral portion of the longitudinal groove 34 formed on the vibrating arm 36 and the outer peripheral portion of the vibrating arm 36, the distance dimension m1 at the plus X-axis side is larger than the distance dimension m2 at the minus X-axis side. To be more specific, it must be made sure that the distance between the outer peripheral portion of the longitudinal groove 34 formed on the vibrating arm 36 and the outer peripheral portion of the vibrating arm 36 is individually arranged at the plus X-axis side and at the minus X-axis side, thereby making it possible to ensure the polarization of electrodes. This dimension yet makes the following possible: By making the distance dimension m1 at the plus X-axis side larger than the distance dimension m2 at the minus X-axis side, thereby making it possible to adequately obtain the above-mentioned structure, in which the center position in width dimension of the longitudinal groove is shifted in the minus X-axis direction.

To be more specific, when the center of the gravity of the vibrating arm 36 is closer to the minus X-axis side from the above-mentioned center line CL by about 3 μm, the center position of the longitudinal groove 34 is shifted to the minus X-axis side so that the center of the gravity of the vibrating arm 36 and the above-mentioned center line CL coincide with each other, the dimension m2 in FIG. 5 becomes extremely small, resulting in that the polarization of electrodes at this position is hardly performed. Therefore, the decentering (position shift) of the longitudinal groove 34 to the minus X-axis side is performed by 1 μm to 3 μm, it becomes possible to obtain relative stable flexural vibration without the above-described adverse effects.

Next, a preferred detailed structure of the resonator element main body 32 according to this embodiment will be described.

Since each of the vibrating arms 35 and 36 of the resonator element main body 32 shown in FIG. 4 has the same shape, only the vibrating arm 36 will be explained. The vibrating arm width is the widest at the base end part T at which each of the vibrating arms extends from the base portion 51. A first reduced width part TL, which drastically reduces its width between the positions of T to U, is formed, where the position T is the footing part of the vibrating arm 36 and the position U is spaced apart from the position T toward the distal part of the vibrating arm 36 by a little distance. A second reduced width part, which gradually and continuously decreases its width from the position U to the position P, namely, across the distance CL of the vibrating arm. The position U is the end of the first reduced width part TL. The position P is spaced apart from the position U further toward the distal part of the vibrating arm 36.

Accordingly, the vibrating arm 36 has a high stiffness with the first reduced width part TL provided at the footing part close to the base. Further, the vibrating arm 36 also has a stiffness continuously decreased with the second reduced width part CL, which is formed from the point U serving as the end of the first reduced width part to the distal part. The part P is the arm width changing point P and is a constricted position of the vibrating arm 36. Thus, it also can be expressed as the constricted position P. In the vibrating arm 36, the arm width extends from the arm width changing point P to the distal part with the same width, or preferably, with the width gradually and slightly enlarged as shown in the figure.

Here, the longer longitudinal grooves 33, 34 in FIG. 4 become, the better the electric field efficiency of the material forming the vibrating arms 35, 36 becomes. Here, the longer the longitudinal grooves, the lower the CI value of the tuning fork type resonator element in the case in which at least jib is up to approximately 0.7, where b is the entire length of vibrating arm and j is the length of the longitudinal grooves 33, 34 from the base portion 51. Therefore, jib is preferably from 0.5 to 0.7. According to this embodiment, the entire length b of the vibrating arm 36 shown in FIG. 4 is, for example, approximately 1100 μm to 1400 μm.

In addition, when the length of the longitudinal groove is adequately elongated so that the CI value is sufficiently suppressed, there arises then a problem in that the CI value ratio (CI value of harmonic wave/CI value of fundamental wave) of the resonator element main body 32.

That is to say, if the CI value of a harmonic wave is smaller than the CI value of the fundamental wave since the CI value of the harmonic wave is simultaneously suppressed by reducing the CI value of the fundamental wave, oscillation with the harmonic wave easily occurs.

In view of this, in addition to elongating the longitudinal groove so that the CI value is reduced, the changing point P is provided more closely to the distal part of the vibrating arm. This allows the CI value ratio (CI value of harmonic wave/CI value of fundamental wave) to be more increased while reducing the CI value.

In other words, the stiffness of the bottom part, i.e. in the vicinity of the footing part, of the vibrating arm 36 is strengthened by the first reduced width part TL. This strengthened stiffness makes the flexural vibration of the vibrating arms more stable. As a result, the CI value can be suppressed.

Since the second reduced width part CL is provided, the stiffness of the vibrating arm 36 is gradually lowered from its footing part, toward the distal part, to the constricted position P serving as the arm width changing point. From the constricted position P to the distal part, the stiffness of the vibrating arm 36 is gradually increased because the longitudinal groove 34 is not provided, and the width of the vibrating arm is gradually widened.

Accordingly, it can be considered that the node of the vibration in the second harmonic wave can be shifted to the position closer to the distal part of the vibrating arm 36. As a result, lowering the CI value of the second harmonic wave cannot be provoked while the CI value of the fundamental wave is suppressed even though the CI value is increased by increasing the electric field efficiency of the piezoelectric material with elongated longitudinal groove 34. Consequently, the CI value ratio is almost certainly increased by preferably providing the arm width changing point P closer to the distal part of the vibrating arm from the end part of the longitudinal groove as shown in FIG. 4, thereby making it possible to prevent the oscillation with the harmonic wave.

Moreover, according to research by the inventor, j/b, an arm width reduced ratio M, and the CI value ratio corresponding to them are correlated where b is the entire length of the vibrating arm, j is the length of the grooves 33, 34 from the base portion 51, M is the ratio of the maximum width and the minimum width of the vibrating arm 35, and CI value ratio is the ratio of the CI value of the second harmonic wave and the CI value of the fundamental wave.

In addition, it was confirmed that the oscillation with harmonic wave was able to be prevented by the CI value ratio that became more than one by increasing the arm width reduced ratio M, which is the ratio of the maximum width and the minimum width of the vibrating arm 35, so as to be more than 1.06 in a case where j/b is 61.5%.

As a result, it becomes possible to provide a piezoelectric resonator element that can control the CI value of the fundamental wave at a low value and do not deteriorate drive level characteristics even though it is wholly miniaturized.

Next, a more preferable structure of the resonator element main body 32 will be explained.

The wafer thickness, i.e. the thickness of quartz wafer forming the piezoelectric resonator element, shown in FIG. 6 as the dimension x is preferably from 70 μm to 130 μm.

The entire length of the resonator element main body 32 shown in FIG. 4, which is indicated by the dimension a, is approximately from 1300 μm to 1600 μm. It is preferable for miniaturizing the piezoelectric device that the dimension b, which is the entire length of the vibrating arm, is from 1100 μm to 1400 μm, while the entire width d of the resonator element main body 32 is from 400 μm to 600 μm. Accordingly, in order to miniaturizing the tuning fork part, the width dimension e of the base portion 51 is preferably from 200 μm to 400 μm.

The dimension k between the vibrating arms 35 and 36 in FIG. 4 is preferably from 50 to 100 μm, for example, 84 μm. If the dimension k is less than 50 μm, it is difficult to sufficiently lessen a fin shaped convex part, which is an irregular shaped part due to an anisotropic etching, in the plus X-axis direction in the side of the vibrating arm shown in FIG. 6 with reference symbol 81 when the outer shape of the resonator element main body 32 is formed by wet etching through the quartz wafer, which will be described later. If the dimension x is 100 μm or more, there arises a problem in that the flexural vibration of vibrating arms may become unstable.

In addition, both dimensions m1 and m2 are from 3 to 15 μm. They are the dimensions between the outer peripheral portion of the longitudinal groove 33 and the outer peripheral portion of the vibrating arm in the vibrating arm 35 (the same holds true for the vibrating arm 36) in FIG. 5. The electric field efficiency is improved by the dimensions m1 and m2 of 15 μm and below. The dimensions m1 and m2 of 3 μm or more have an advantage to reliably perform a polarization of electrodes.

The first reduced width part TL having the width dimension n of 11 μm or more in the vibrating arm 36 in FIG. 4 can be expected to show a definite effect on suppressing the CI value.

In the case of the vibrating arm 36 in FIG. 4, it is preferable that the arm width be widened from the arm width changing point P to the distal part by approximately from zero to 20 μm with respect to the width of the arm width changing point P, which is the position at which the arm width of the vibrating arm 36 is the minimum. Widening the width over the width described above has a risk of deteriorating stability of the flexural vibration, since the distal part of the vibrating arm 36 is too heavily weighted.

An irregular shaped part 81 is formed on one side of the outside of the vibrating arm 35 (the same holds true of the vibrating arm 36) in FIG. 6. The irregular shaped part 81 has a fin shape and protrudes in the plus X-axis direction. This is formed as etching remains due to the anisotropic etching of quartz when the piezoelectric resonator element is wet etched for forming its outer shape. In order to achieve the stable flexural vibration of the vibrating arm 35, it is preferable that the protruded amount v of the irregular shaped part 81 be reduced within 5 μm by performing the etching in the etching solution containing hydrofluoric acid and ammonium fluoride for 9 to 11 hours.

It is preferable that the width dimension of the longitudinal groove, which is denoted by the dimension g in FIG. 4, is approximately from 60 to 90% with respect to the arm width C of vibrating arm in the region, in which the longitudinal groove is formed, of the vibrating arm. The arm width C varies at the position along the longitudinal direction of the vibrating arm since the first and second reduced width parts are formed to the vibrating arms 35, 36. The width g of the longitudinal groove is approximately from 60 to 90% with respect to the maximum width of the vibrating arm. If the width of the longitudinal groove is smaller than this, the electric field efficiency is lowered, resulting in the CI value being increased.

Moreover, the position of the end part, which is adjacent to the base portion 51, of the longitudinal grooves 33, 34 is preferably the same as the footing part of the vibrating arms 35, 36, i.e., the position T, or is in the range in which the first reduced width part TL is present and slightly spaced apart from the position T toward the distal part of the vibrating arm, and, particularly, is not preferably adjacent to the base end of the base portion 51 from the position T.

FIG. 7 is a circuit diagram illustrating an example of an oscillation circuit when a piezoelectric oscillator is constructed by using the piezoelectric device 30 according to this embodiment.

An oscillation circuit 91 includes an amplifying circuit 92 and a feedback circuit 93.

The amplifying circuit 92 is constructed by including an amplifier 95 and a feedback resistor 94. The feedback circuit 93 is constructed by including a drain resistor 96, capacitors 97, 98, and the resonator element main body 32.

As shown in FIG. 7, the feedback resistor 94 is, for example, approximately 10 MΩ (mega ohm). The amplifier 95 can employ a CMOS inverter. The drain resistor 96 is, for example, from 200 to 900 kΩ. (kilo ohm). Each of the capacitor 97 (drain capacitance) and the capacitor 97 (gate capacitance) is from 10 to 20 pF (pico farad).

The piezoelectric device according to this embodiment is constructed as described above. The package 57 which houses the resonator element main body 32 as the piezoelectric resonator element is formed by the base substrate 54 and the frame portion 54 of the framed resonator element 55, which is stacked on the base substrate and the lid 56 is stacked on the frame portion and the entire assembly is sealed so as to be airtight.

Therefore, the resonator element main body 32 is formed so as to be integral with the frame portion 53, so there is no need of bonding it on the package 57 by using adhesive or the like and there arise no difficulties in bonding even when it downsized.

Since the same material is used of the base substrate 54, the framed resonator element 55 stacked and fixed on the base substrate, and the lid stacked and fixed on the framed resonator element 55, so no stress due to change in temperature environment is imparted to the bonding portions even if they are bonded to each other in a stacked manner.

As described later with respect to the manufacturing process, plasma irradiation is performed to the respective bonding surfaces of the base substrate 54 and the framed resonator element and the lid 56 so as to activate the surfaces of the bonding surfaces (surface activated bonding), it becomes possible to adequately bond even the same materials. Further, heating is not necessary for bonding, so a structure according to which adverse effects due to heat is avoided can be realized.

As thus described above, it is possible to provide the piezoelectric device 30 having excellent drive level characteristics in terms of downsizing, having no remaining stress at the bonding portion of the container and leaving no characteristics deteriorating factors.

(A First Embodiment of Method for Manufacturing Piezoelectric Device)

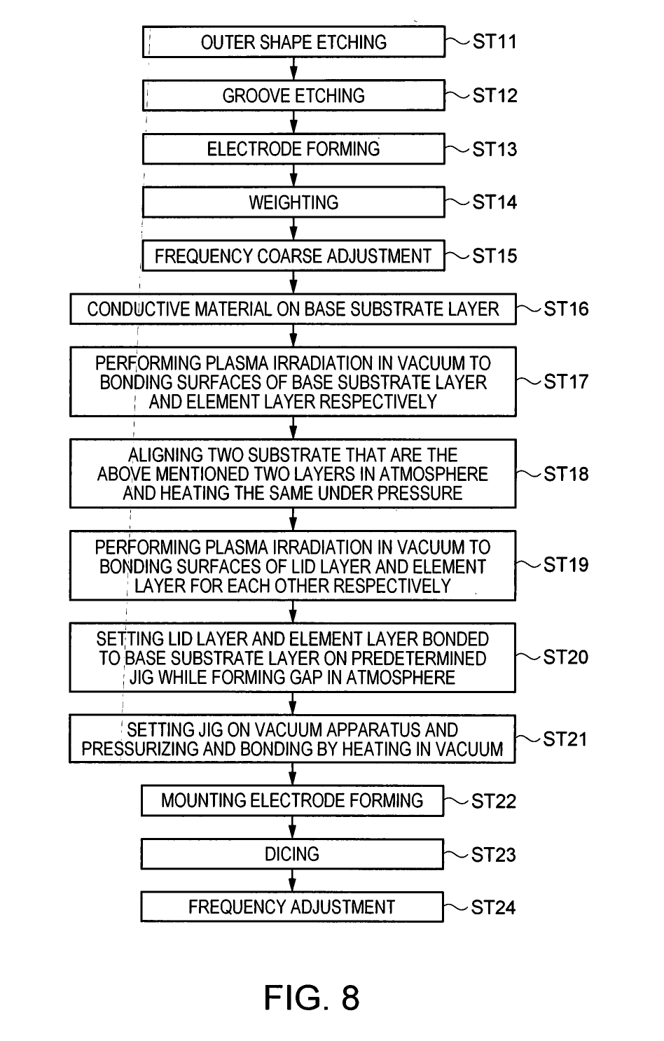

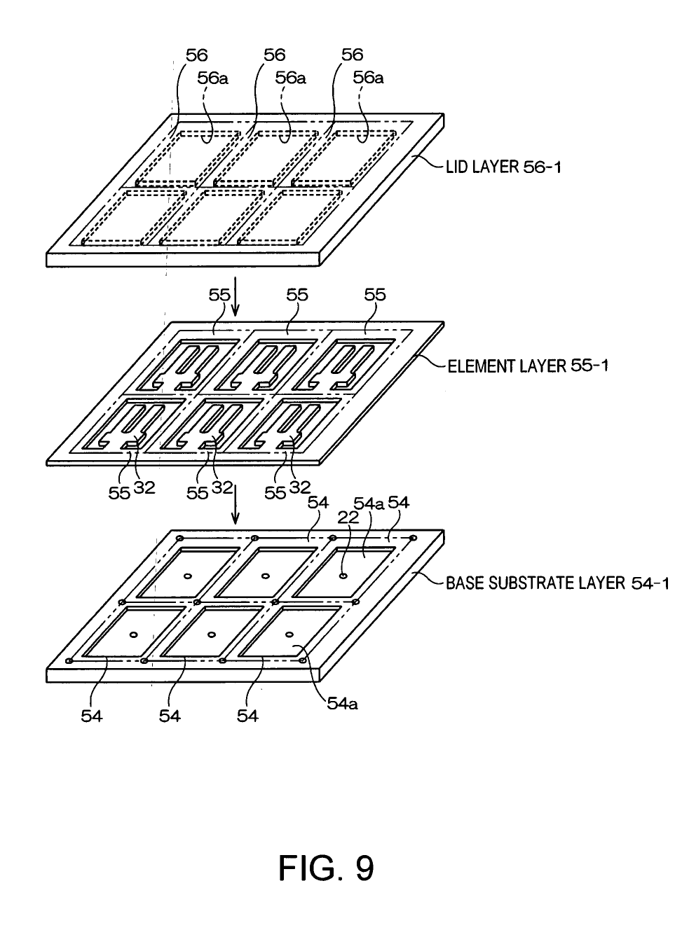

Next, with reference to a flow chart of FIG. 8 and (a part of) a process chart of FIG. 9, a first embodiment of the method for manufacturing the above-mentioned piezoelectric device 30.

The method for manufacturing the piezoelectric device 30 is divided into a pre-process and a post-process.

(Pre-Process)

The pre-process of the method for manufacturing the piezoelectric device 30 includes a base substrate layer forming step, in which a plurality of base substrates 54 are formed at the same time, a element layer forming step, in which a plurality of framed resonator elements are formed at the same time, and a lid layer forming step, in which a plurality of lids are formed at the same time. The base substrate layer forming step, the element layer forming step, and the lid layer forming step are steps, which are individually carried out. That is to say, the pre-process is a preparation process for assembly, in which a plurality of steps is carried out in a parallel manner. Note that those steps are carried out according to substantially the same manner and will be therefore collectively described.

As shown in FIG. 9, the base substrate layer 54-1 is a wafer with a plurality of or a lot of base substrates 54 being lengthwise and crosswise arranged. The element layer 55-1 is a wafer with a plurality of or a lot of framed resonator elements 55 being lengthwise and crosswise arranged. The lid layer 56-1 is a wafer with a plurality of or a lot of lids 56 being lengthwise and crosswise arranged. All of them are quartz wafers described above in details.

As for the lid layer 56-1, a lot of recesses 56a can be formed at the same time by, for example, dry etching or wet etching.

In the same manner, as for the base substrate layer 54-1, a lot of recesses 54a are formed at the same time by etching, as described above and etching is carried out to form a lot of through-holes 22 at the same time. As for the base substrate layer 54-1, the conductive through hole shown in FIG. 1 is formed by etching, on which chrome and gold films are successively formed by deposition, sputtering, plating or the like, thereby making it possible to form the electrode parts 23, 24, 25 and the conductive pattern 24a, the mounting terminals 26, 27 or the like. In the case of the mounting terminals 26, 27, they can formed by forming chrome film by sputtering and patterning gold thereon before performing nickel plating and then gold plating thereon.

Referring to FIG. 8, the treatment of the element layer 55-1 will be described.

A quartz wafer for forming the element layer 55-1 is prepared and subjected to etching by fluorinated solution. Then, the outer shape described with reference to FIG. 4 can be formed (ST11).

Next, the longitudinal grooves 34, 34 described with reference to FIG. 4 are formed by half etching (ST12). Then, a electrode forming step in which the excitation electrodes 37, 38 as electrodes for driving and the led-out electrodes 37a, 38a is carried out (ST13).

The electrode film is formed from, for example, a foundation layer and an electrode layer. As the foundation layer, chrome or nickel is suitable. As the electrode layer, gold is suitable. Further, on the distal parts of each of the vibrating arms 35, 36 of the resonator element main body 32, there are deposited a weighting electrode 21 for frequency adjustment described with reference to FIG. 1 by continuously carrying out sputtering (ST14).

Next, a predetermined drive voltage is applied to the element layer 55-1 by the passage of electric current before bonding, thereby adding an electrode while monitoring frequency outputted by excitation, or trimming by laser light so as to carry out frequency coarse adjustment (ST15). Note that apart from the element layer 55-1, an electrode part is formed on the base substrate layer 54-1 (ST16).

(Bonding Process)

(Surface Activating Process)

According to this invention, a surface activating treatment is carried out before performing a bonding process/To be more specific, as for bonding of such type, bonding such as anodic bonding, which is carried out while being heated, has been employed. The “anodic bonding” is a technique, according to which the surfaces are brought into close contact with each other and bonded with solid phase. According to the anodic bonding, it is assumed that electrostatic attraction is generated between the bonding surfaces, which then come to close contact with each other. Then, ion movement is accelerated from the glass side toward the electrode side by intense electric field. At the interface, covalent-bonding with atom at the electrode side is generated so that the bonding is performed. Therefore, the material such as glass for generating ion and the metal film or the like are bonded with each other through activity of electric filed, and the same materials cannot be bonded with each other.

Further, the bonding is carried out during heating, so it is necessary to forming an environment in which heat and electric field act, which is not only bothersome but also may result in that the remaining thermal stress after bonding has adverse effects on products.

On the other hand, according to the surface activating bonding, the surfaces of the bonding surfaces are activated, thereby performing bonding. To be more specific, dirt such as an oxidized film, water molecule adsorbed or organic molecule, for example, that is, hindrance of bonding except the surface layer are removed (physical treatment process). Then, the bonding surface is reformed and activated (chemical treatment process), thereby adding OH-base as coupling hand on the respective bonding surfaces so as to bring the bonding surfaces into contact with each other. Therefore, heating is not necessarily carried out (when the heating can be performed environmentally, the heating may be performed). Intense electric field is not necessary, so the surface activating bonding has no disadvantages of anodic bonding and further has excellent characteristics that the same materials can be bonded with each other.

Therefore, the bonding surfaces of the respective layers to be bonded are subjected to plasma irradiation (ST17).

Specifically, the base substrate layer 54-1 and the element layer 55-1 are arranged in a vacuum chamber and a predetermined masking is performed so that the bonding surfaces of the respective layers bonded with each other are made to be exposed. As the plasma treatment types, RIE (Reactive Ion Etching) can be employed and an ICP (Inductively Coupled Plasma) type RIE reactor and a SWP (Surface Wave Plasma) type RIE reactor can be suitably used.

For the physical treatment for removing mainly pollution on the surface, plasma utilizing gases such as Ar, CF₄, and Nr is generated, thereby making it possible to perform treatment.

For the above-mentioned activation, that is, chemical treatment, plasma utilizing gases such as O₂, O₂+CF₄, and O₂+N₂ is generated, thereby making it possible to perform treatment.

According to this embodiment, as the physical treatment, Ar gas is introduced into the vacuum chamber, the degree of vacuum in the vacuum chamber is made 20 to 30 Pas, and plasma treatment is carried out for about 1 minute. Further, as the chemical treatment, O₂+N₂ gas is introduced into the vacuum chamber, the degree of vacuum in the vacuum chamber is made 20 to 30 Pas, and plasma treatment is carried out for about 1 minute.

Next, the bonding surfaces of the base substrate layer 54-1 and the element layer 55-1, whose surfaces are activated by plasma irradiation, are brought into contact with each other and aligned in atmosphere. Then, they are pressurized and bonded with each other while being heated at, for example, about 100 degrees (Celsius) (Note that the following temperature indication is based on the Celsius scale) (ST18). That is to say, in this process, not only the bonding of the base substrate layer 54-1 and the element layer 55-1 but also bonding by heating and pressurizing of the metal bump 51a, which has been described with reference to FIG. 1 and FIG. 2.

Next, the bonding surfaces, at which the element layer 55-1 and the lid layer 56-1 are bonded with each other in vacuum, is subjected to plasma irradiation in vacuum (ST19).

The plasma irradiation is carried out in the same manner as the procedure described with reference to ST17.

Next, the bonding surfaces of the element layer 55-1 and the lid layer 56-1, which are activated by plasma irradiation, are made to face each other and then set on a predetermined jig in atmosphere with a predetermined gap being kept therebetween (ST20).

The above-mentioned jig is put into the vacuum chamber and the degree of vacuum is made about 105 Torr. Then, pressurizing is carried out at the temperature of 200 to 250 degrees and for about 30 minutes (ST21).

Accordingly, bonding is performed. By carrying out bonding in vacuum, the following advantage is obtained. That is to say, the package is subjected to vacuum sealing at a high accuracy by bonding through pressurization in vacuum. As a result, there is nor fear of imparting vibration performance of the piezoelectric resonator element to be contained. Therefore, a low CI (crystal impedance) value at the practicable level can be achieved.

Then, all of the layers of FIG. 9 are bonded with each other, so the mounting terminals 26, 27 described with reference to FIG. 3(b) are formed on the bottom surface (back surface) of the base substrate layer 54-1. In this case, the mounting terminals can be formed by gold plating on the foundation layer made from nickel (ST22).

Next, as shown in FIG. 9 the cutting is performed along the cutting lines denoted by chain lines extending lengthwise and crosswise in the respective layers (cutting process) (ST23).

Finally, by performing irradiation using laser light, for example, from outside, which passes through the respective lids of the piezoelectric device 30 the weighting electrode 21 is trimmed, which is at the distal end of each of the vibrating arms of the resonator element main body 32, thereby performing frequency adjustment (fine adjustment) according to a frequency reducing technique (ST24).

As thus described above, the piezoelectric device 30 is completed.

According to this embodiment of the method for manufacturing, the bonding surfaces of the base substrate layer 54-1, the element layer 55-1 and the lid layer 56-1 are subjected to irradiation of plasma or the like and activated, thereby making it possible to achieve the structure in which even the same materials can be adequately bonded with each other. Then, the cutting process by dicing is carried out after dicing, a lot of piezoelectric devices 30 can be effectively produced at the same time. Further, it is possible to provide the method for manufacturing according to which drive level characteristics are excellent, stress does not remain at the bonding portion of the container and no characteristics deteriorating factor is left.

(Second Embodiment of Method for Manufacturing Piezoelectric Device)

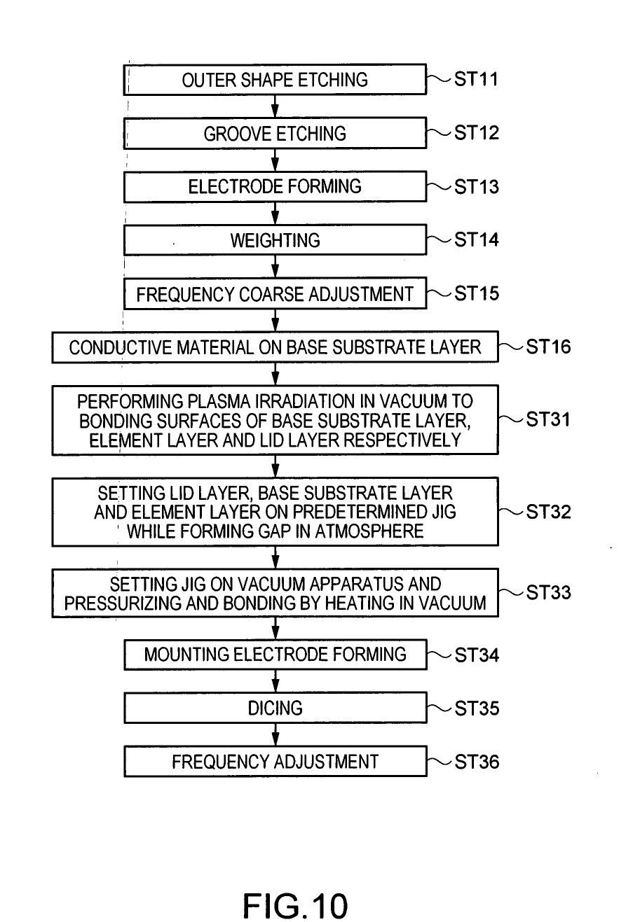

Next, with reference to the flow chart shown in FIG. 10, a second embodiment of the method for manufacturing the above-mentioned piezoelectric device 30.

The pre-process of the manufacturing process of the piezoelectric device 30 and the processes between ST11 and ST16 are common to the first embodiment and the second embodiment. As for the processes similar to those of the first embodiment, a duplicate explanation will be omitted and differences are mainly described below.

(Bonding Process)

(Surface Activating Process)

The surface activating process according to this embodiment is the same as that of the first embodiment.

All of the base substrate layer 54-1, the element layer 55-1, and the lid layer 56-1 shown in FIG. 9 are laid into, for example, a vacuum chamber and a predetermined masking is performed so that the respective bonding surfaces of the layers to be bonded with each other are exposed and subjected to plasma irradiation (ST31).

Next, the base substrate layer 54-1, the element layer 55-1, and lid layer 56-1, whose bonding surfaces after plasma irradiation have been activated, are taken out from the vacuum chamber and are set on a predetermined jig in atmosphere with a predetermined gap respectively therebetween (ST32).

The above-mentioned jig is introduced into the vacuum chamber. The degree of vacuum is made about 105 Torr and pressurization is carried out at the temperature of about 200 to 250 and for about 30 minutes, thereby carrying out bonding. In this process, not only the bonding of the base substrate layer 54-1 and the element layer 55-1, and the lid layer 56-1 but also bonding by heating and pressurizing of the metal bump 51a, which has been described with reference to FIG. 1 and FIG. 2 (ST33).

The following processes are similar to the process from ST22 onward according to the first embodiment.

The second embodiment is structured as described above. Since the surfaces of all of the base substrate layer 54-1, the element layer 55-1, and the lid layer 56-1 are activated, the efficiency is enhanced by just that much. Otherwise, the same operation effects are obtained as of the first embodiment.

(Third Embodiment of Method for Manufacturing Piezoelectric Device)

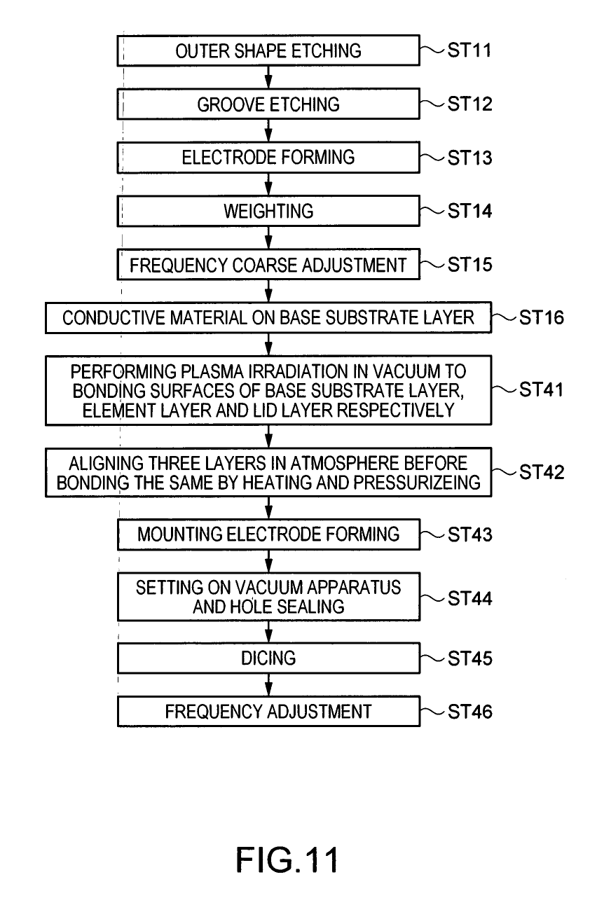

Next, with reference to the flow chart shown in FIG. 11, a third embodiment of the method for manufacturing the above-mentioned piezoelectric device 30 will be described.

The pre-process of the manufacturing process of the piezoelectric device 30 and the processes between ST11 and ST16 are common to the first embodiment and the third embodiment. As for the processes similar to those of the first embodiment, a duplicate explanation will be omitted and differences are mainly described below.

The base substrate layer 54-1, the element layer 55-1, and the lid layer 56-1 shown in FIG. 9 are laid into, for example, a vacuum chamber and a predetermined masking is performed so that the respective bonding surfaces of the layers to be bonded with each other are exposed. Then, those exposed bonding surfaces are subjected to plasma irradiation (ST41).

The conditions etc. of the plasma irradiation are similar to those of the first embodiment.

Then, the bonding surfaces of the base substrate layer 54-1, the element layer 55-1 and the lid layer 56-1, which are activated by plasma irradiation, are made to face each other and then set on a predetermined jig in atmosphere with a predetermined gap being kept therebetween before being heated and pressurized. In this process, not only the bonding of the base substrate layer 54-1, the element layer 55-1, and the lid layer 56-1 but also bonding by heating and pressurizing of the metal bump 51a, which has been described with reference to FIG. 1 and FIG. 2 (ST42).

All of the layers shown in FIG. 9 are thus bonded with each other, the mounting terminals 26, 27, which have been described with reference to FIG. 3(b), are formed on the bottom surface (back surface) of the base substrate layer 54-1 (ST43).

Then, for example, three layers are places upside down in, for example, a vacuum chamber while being bonded with each other and metal bolls made from gold germanium are laid on the respective through-holes 22. Those metal bolls are molten successively or at the same time under heat by performing laser light irradiation and the through-holes 22 are filled with thus molten metal. At the same time, gas inside the package 57 is discharged from the through-holes 22 (hole sealing). By this, the package 57 is sealed airtight (ST44).

The following ST 45, ST46 are similar to ST23, ST24 according to the first embodiment, respectively.

The third embodiment is structured as described above. Since the surfaces of all of the base substrate layer 54-1, the element layer 55-1, and the lid layer 56-1 are activated, the efficiency is enhanced by just that much. Further, the process of hole sealing (ST44) is carried out so that the adhesion of gas on the resonator element main body can be prevented, thereby enhancing the product quality.

Otherwise, the same operation effects are obtained as of the first embodiment.

It should be understood that the invention is not limited to the above-described embodiments. The structure of each embodiment can be appropriately combined or omitted, and an additional structure not shown can also be combined therewith.

In addition, the invention can be applied to not only one in which the piezoelectric resonator element is housed in a box shaped package, but also to one in which the piezoelectric resonator element is housed in a cylindrical package, one in which the piezoelectric resonator element serves as a gyro sensor, and further to any piezoelectric devices utilizing the piezoelectric resonator element regardless of the name of the piezoelectric resonator, piezoelectric oscillator, etc. Moreover, a pair of vibrating arms is formed in the resonator element main body 32. However, the number of vibrating arms is not limited to this, but can be three or more.

1. A piezoelectric device, comprising:
a base substrate, a framed resonator element stacked and fixed on the base substrate, a lid stacked and fixed on the framed resonator element, characterized in that:
the base substrate, the framed resonator element, and the lid are made of at least one of same material and materials having highly approximate linear coefficients of expansions, and bonding surfaces thereof are bonded with each other by surface activating process so as to be vacuum-sealed.

2. The piezoelectric device according to claim 1, characterized in that the base substrate, the framed resonator element, and the lid are all made of quartzes having same cut angle.

3. The piezoelectric device according to claim 1, characterized in that:
the frame resonator element has a piezoelectric resonator element portion and a frame portion formed so as to surround the piezoelectric resonator element portion;
a resonator element main body as the piezoelectric resonator element portion has a base portion inwardly extending, within the frame portion, from a side constituting the frame portion and a plurality of vibrating arms extending from the base portion;
a longitudinal groove is formed on each of the plurality of vibrating arms, the longitudinal groove formed on the main surface of the vibrating arms in longitudinal direction and having a drive electrode therewithin; and
a width dimension of each of the vibrating arms has a reduced width part gradually reducing its width from the base portion side toward the distal end side, a changing point P of width change is located on the distal end side, at which the width dimension extends with an equal amount or increases, and the changing point P is located nearer to vibrating arm distal end side than the distal part of the longitudinal groove.

4. The piezoelectric device according to claim 3, characterized in that:
the width dimension of each of the vibrating arms has a first reduced width part drastically reducing its width from a footing part of the vibrating arm to the base portion toward the distal part thereof, and a second reduced width part gradually decreasing its width as a reduced width part from the end of the first reduced width part further toward the distal part thereof.

5. The piezoelectric device according to claim 3, characterized in that the base portion has a cut portion formed to be reduced in its width.

6. The piezoelectric device according to claim 5, characterized in that the cut portion is formed on the base portion with a more than 1.2 times distance of the arm width from the footing part of each of the vibrating arms.

7. The piezoelectric device according to claim 3, characterized in that the base portion is provided with a through-hole located at the position closer to the vibrating arm than the position, at which the frame portion is integrally connected to the base portion.

8. The piezoelectric device according to claim 3, characterized in that an irregular shaped part projecting in a plus X-axis (electric axis) direction of less than 5 μm is formed on a lateral surface of each of the vibrating arms.

9. The piezoelectric device according to claim 3, characterized in that the center position in width dimension of the longitudinal groove of each of the vibrating arms is shifted in a minus X-axis direction from the center position of the arm width dimension.

10. A method for manufacturing a piezoelectric device, comprising:
forming a base substrate layer constituting base substrate, an element layer constituting a framed piezoelectric resonator element, and a lid layer constituting a lid, the layers being formed from at least one of same material and the materials having highly approximate linear coefficients of expansion, and having the sizes corresponding to the same numbers of a plurality of products;
performing surface activating to bonding surfaces of the base substrate layer, the element layer, and the lid layer;
staking and pressurizing the layers to bond the same with each other; and
cutting the respective layers into a piece of a size corresponding to the respective product.

11. The method for manufacturing the piezoelectric device according to claim 10, characterized in that the step of staking and pressurizing the layers is carried out in vacuum so that airtight sealing is performed.

12. The method for manufacturing a piezoelectric device according to claim 10, characterized in that the step of staking and pressurizing is carried out in atmosphere and then hole sealing is performed in vacuum so that airtight sealing is performed.

13. The method for manufacturing a piezoelectric device according to any one of claims 10 to 12, characterized in that: plasma irradiation of the bonding surfaces is carried out in vacuum prior to the respective bonding surfaces of the element layer and the base substrate layer or of the element layer and the lid layer and those are aligned in atmosphere and subjected to bonding process for bonding; and that the other bonding surface is then subjected to plasma irradiation in vacuum and aligned in atmosphere before being subjected to bonding process in vacuum.
